(19) United States
(12) Patent Application Publication
(10) Pub. No.: US 2001/0045320 A1
(43) Pub. Date: Nov. 29, 2001

(54) Speaker unit

(76) Inventors: Shigeru Sugiyama, Shizuoka (JP); Hajime Kitamura, Shizuoka (JP); Naohiro Fujinami, Shizuoka (JP)

Correspondence Address: SUGHRUE, MION, ZINN, MACPEAK & SEAS, PLLC, 2100 Pennsylvania Avenue, N.W., Washington, DC, 20037-3202, US

(21) Appl. No.: 09/825,302

(22) Filed: Apr. 4, 2001

(30) Foreign Application Priority Data
Apr. 4, 2000 (JP) P. 2000-102801

(51) Int. Cl. H05K 5/00

(52) U.S. Cl. 181/153; 181/148

(57) ABSTRACT

In a speaker unit, a case 40 is formed of a synthetic resin member having a case body 42 and a protective cover 44 integrally molded. Further, an opening portion 48 is formed in a surrounding wall 46 of the case body 42 and a beam 50 is formed inside of the case body 42. In a state where the speaker 20 is inserted into the case body 42 through the opening portion 48, the speaker 20 is held by the beam 50 and the protective cover 44 from its upside and downside.

### BACKGROUND OF THE INVENTION

1. Field of the Invention

The present invention relates to a speaker unit having a speaker and a case for storing the speaker therein.

2. Description of the Related Art

Generally, a speaker is used as a speaker unit in a state where it is stored in a case. Up to now, there has been known that the case includes a cylindrical case body for holding a frame of the speaker and a protective cover for partially covering a diaphragm of the speaker at a leading end of this case body.

The protective cover is formed of a member designed to prevent a finger or the like from touching the diaphragm carelessly. The protective cover fixed to the case body or the frame of the speaker by bonding, deposition or the like has been known up to now.

However, in the above conventional speaker unit, the case is comprised of two members, that is, the case body and the protective cover; and a process for fixing the two members to each other is required. Therefore, its manufacturing cost becomes high.

### SUMMARY OF THE INVENTION

The invention has been made in view of these circumstances, and an object of the invention is to provide a speaker unit having a speaker and a case for accommodating this speaker therein, which can be manufactured at low costs.

To achieve the above object, according to the invention, there is provided a speaker unit comprising:

a speaker having a diaphragm; and

a case for storing said speaker therein, said case comprising a cylindrical case body and a protective cover for partially covering the diaphragm at the leading end of said case body;

wherein said cylindrical case body and said protective cover are integrally molded of synthetic resin;

wherein an opening portion is defined in a surrounding wall of said case body through which the speaker is inserted;

and

wherein a beam is formed inside of said case body, whereby said speaker is held by said beam and said protective cover in a state where said speaker is inserted into said case body.

In the invention, a kind of the speaker is not particularly limited. For example, a dynamic speaker, a piezoelectric speaker, etc., are applicable.

Also, the beam is not particularly limited to a specific structure as long as the speaker can be held by the beam and the protective cover.

As indicated in the above constitution, in the speaker unit according to the invention, since the case is made of synthetic resin comprising the cylindrical case body and the protective cover integrally molded, the number of parts to be used in the speaker unit is reduced by one and no process of fixing the case body and the protective cover to each other is required, as compared with the conventional speaker unit in which the case body and the protective cover are formed of different members. Further, in the speaker unit according to the invention, since the speaker inserted into the case body through the opening portion formed in the surrounding wall of the case body is held by the beam formed inside of the case body and the protective cover, the case integrally molded as described above can be readily realized.

Therefore, according to the invention, since the speaker unit having the speaker and the case for storing the speaker therein can be readily constituted as an integrally molded product, the speaker unit can be manufactured at the low costs.

Further, in the speaker unit according to the invention, since the speaker is held by the beam and the protective cover in a state where the speaker is inserted into the case body through the opening portion, the speaker can be readily inserted into the case.

In the above constitution, since the beam is formed at a position where the beam does not overlap with the protective cover when the case is seen from the leading end side, the case can be molded without using a slide mold.

Further, in the above constitution, since a fitting structure that fits to each other when the speaker is inserted into the case body is provided on the speaker and the case, the speaker can be firmly inserted into the case.

In the invention, the fitting structure is not limited to a specific structure. The fitting structure may be a projection formed on a frame of the speaker and a recess portion formed in the protective cover. Thus, the fitting structure can be realized with a simple constitution.

In this case, since the projection is caulked and fixed to the protective cover in a state where the projection is fitted to the recess portion, the speaker can be more firmly fixed to the case.

Further, in the above constitution, since at least a part of the protective cover is formed of a pair of flexible levers that extend opposite to the inserted direction of the speaker, and the above recess portions are formed in the vicinity of the leading end portions of those flexible levers, respectively, the projections can be fitted to the recess portions due to the elastic force of both the flexible levers, thereby enabling fitting between the projections and the recess portions smoothly and firmly.

Since the speaker is so designed as to extend a pair of terminal pins out of a peripheral edge portion thereof, and fixing portions that fit to the respective terminal pins are formed on the surrounding wall of the case body, the respective terminal pins can be firmly positioned at predetermined positions with respect to the case body when the speaker is inserted into the case body. Accordingly, when the speaker unit is attached to an attachment such as abase plate, attaching operation can be performed in a state where the positional relation between the attaching portion of the case body and the respective terminal pins is accurately held, with the result that the attaching workability of the speaker unit can be enhanced.

### BRIEF DESCRIPTION OF THE DRAWINGS

FIG. 1 is a perspective view showing a speaker unit according to an embodiment of the invention, viewed from a front surface (speaker inserted direction) in a state where the speaker unit is arranged face up;

FIG. 2 is a sectional view taken along a line of II-II in FIG. 1;

FIG. 3 is a diagram similar to FIG. 1, singly showing a speaker of the above speaker unit;

FIG. 4 is a diagram similar to FIG. 1, singly showing a case of the above speaker unit;

FIG. 5 is a diagram showing the case, viewed from the upside;

FIG. 6 is a diagram similar to FIG. 2, showing a state where the above speaker is going to be inserted into the case;

and

FIG. 7 is a diagram similar to FIG. 5, showing the action of the speaker unit according to the embodiment.

### DETAILED DESCRIPTION OF THE PREFERRED EMBODIMENTS

Now, a description will be given in more detail of preferred embodiment of the invention with reference to the accompanying drawings.

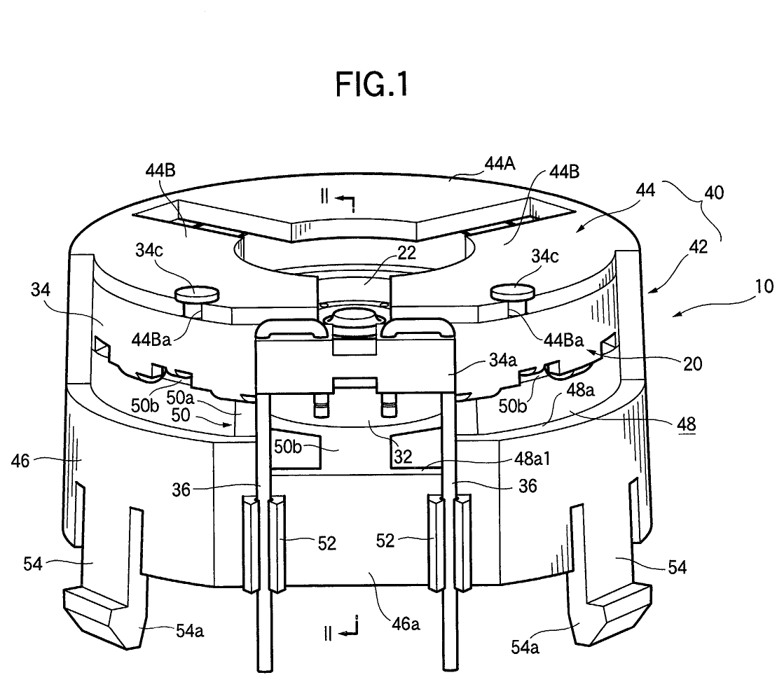

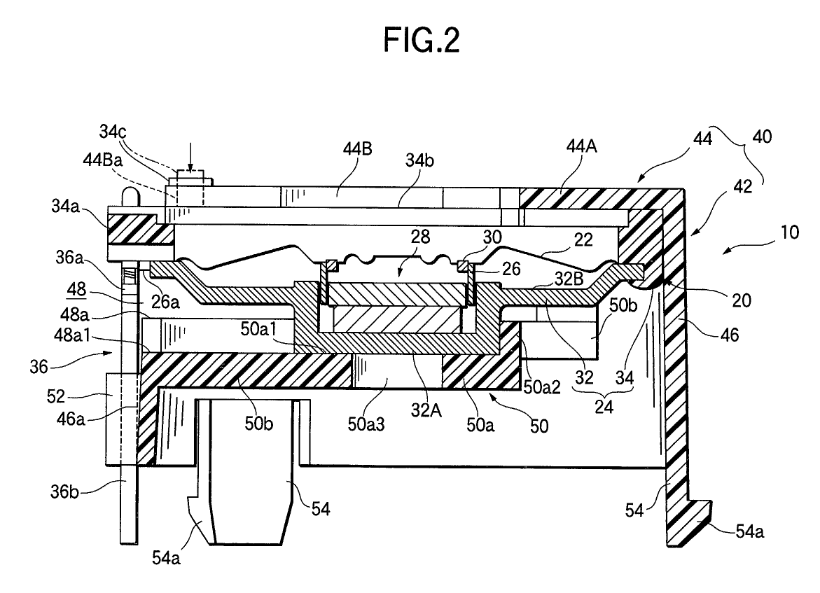

FIG. 1 is a perspective view showing a speaker unit 10 according to an embodiment of the invention, viewed from the upside in the front direction (speaker inserted direction) in a state where the speaker is arranged face up. FIG. 2 is a sectional view taken along a line of II-II in FIG. 1.

As shown in those figures, the speaker unit 10 according to this embodiment includes a speaker 20 and a case 40 for storing this speaker 20 therein.

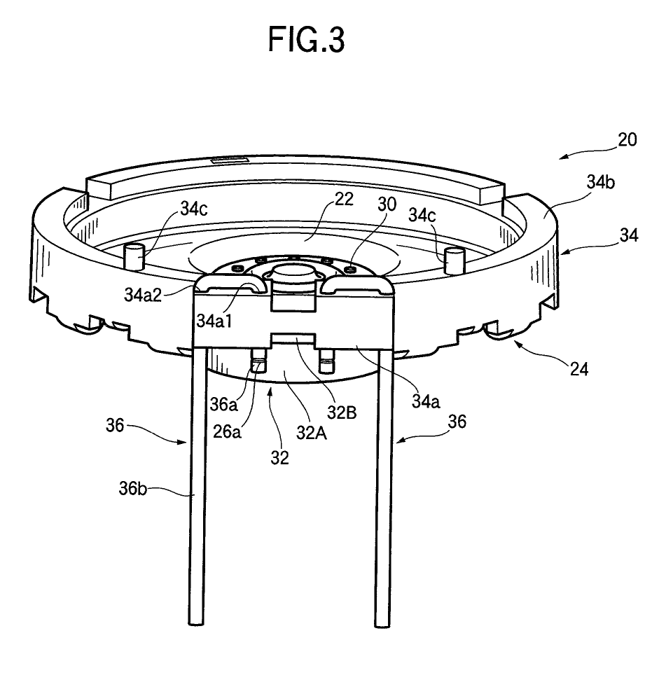

The speaker 20, as shown singly in FIG. 3, is a dynamic speaker including a diaphragm 22, a frame 24 for supporting the diaphragm 22, a voice coil 26 an upper end portion of which is fixed through a coil supporting member 30 to the diaphragm 22, and a magnetic circuit unit 28 in which a cylindrical magnetic gap that stores a lower end portion of the voice coil 26 therein is formed. The speaker 20 is a small-sized speaker having an outer diameter of about 30 mm and stored in the case 40 to be the speaker unit 10. The speaker unit 10 is mounted on a substrate and loaded on an automobile or the like so as to be used as means for generating alarm sound or the like.

The frame 24 is formed by caulking and fixing a base 32 made of steel and a ring 34 made of synthetic resin.

The base 32 includes a bottomed cylindrical portion 32A that protrudes downward in a cylindrical manner at a center portion thereof and an annular mounting portion 32B that extends radially outwardly from the vicinity of an upper end portion of an outer surface of the bottomed cylindrical portion 32A. On the other hand, the ring 34 is formed annularly along the configuration of the outer peripheral edge portion of the diaphragm 22, and caulked and fixed to the mounting portion 32B so that the outer peripheral edge portion of the diaphragm 22 is held by a lower end surface of the ring 34 and the outer peripheral edge portion of the mounting portion 32B. The ring 34 is caulked and fixed also to the outer peripheral edge portion of the diaphragm 22.

A terminal attaching flange 34a is formed on the outer peripheral surface of the ring 34, and a pair of terminal pins 36 is fixed to the terminal attaching flange 34a. Each of those terminal pins 36 is a nearly reverse J-shaped member having a shorter leg portion 36a and a longer leg portion 36b which extend downward. The shorter leg portion 36a is press-inserted from the upside into a terminal supporting hole 34a1 formed in a terminal attaching flange 34a, and the longer leg portion 36b is fitted to a terminal fitting groove 34a2 formed in the terminal attaching flange 34a. End portions of a pair of lead wires 26a extending from the voice coil 26 are wound and fixed on the shorter leg portions 36a of those terminal pins 36, respectively.

Further, a pair of columnar projections 34c is formed in the vicinity of the right and left sides of the terminal attaching flange 34a on an upper end surface 34b of the ring 34.

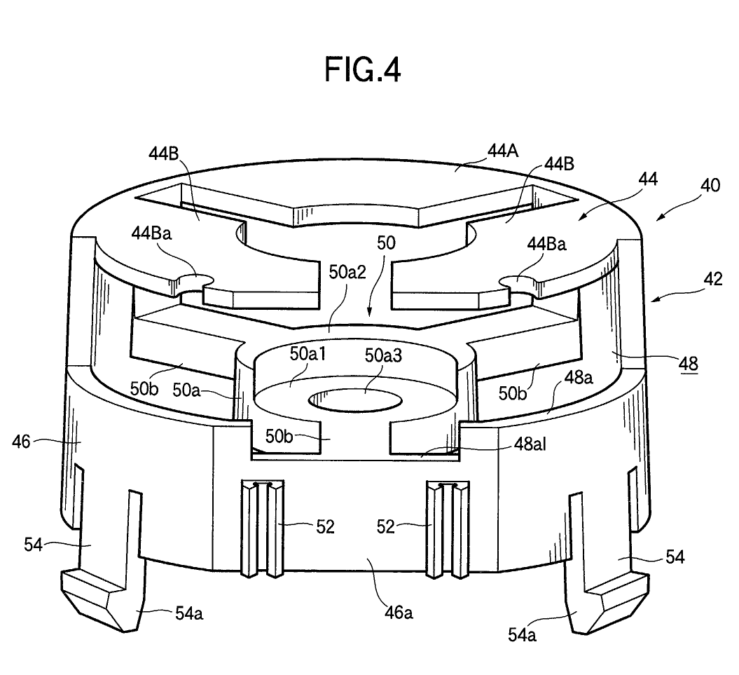

On the other hand, the case 40, as shown singly in FIG. 4, is formed of a synthetic resin member having a cylindrical case body 42 and a protective cover 44 integrally molded. The protective cover 44 partially covers a diaphragm 22 of the speaker 20 at the upper end (leading end) of the case body 42.

A front side of a surrounding wall 46 of the case body 42 is partially chamfered into a flat portion 46a. An opening portion 48 is formed at the upper portion of the surrounding wall 46. The opening portion 48 is formed in a range of an angle of 180° on the front side of the surrounding wall 46. A lower end edge 48a of the opening portion 48 in the flat portion 46a is formed as a step-down portion 48a1 having the bilateral width of the nearly same dimension as that of the outer diameter of the bottomed cylindrical portion 32A of the base 32 of the speaker 20. The step-down amount of the step-down portion 48a1 is set smaller than the downward protruding amount of the bottomed cylindrical portion 32A. Further, the height from the step-down portion 48a1 to the lower surface of the protective cover 44 is set to substantially the same as the height from the lower end surface of the bottomed cylindrical portion 32A in the speaker 20 to the upper end surface 34b of the ring 34.

A beam 50 is formed inside of the case body 42. The beam 50 includes a hub 50a located in the center of the case body 42 and three spokes 50b extending horizontally from the hub 50a to the surrounding wall 46 at intervals of 120° in the circumferential direction.

One of those three spokes 50b extends to the front side, and an upper surface thereof is set to the same level as the step-down portion 48a1 of the lower end edge 48a of the opening portion 48. The upper surface of each of other two spokes 50b is set to the same level as the other portion of the lower end edge 48a.

On the other hand, the hub 50a is substantially cylindrically shaped, and a central portion 50a1 thereof and an upper surface of that portion on the front side are formed at the same level as the upper surface of the spoke 50b on the front side. The upper surface of a surrounding edge portion 50a2 other than the central portion 50a1, which is substantially U-shaped, is formed at the same level as the upper surfaces of other two spokes 50b. The bilateral width of the inner surface of the surrounding edge portion 50a2 is set to the same value as the bilateral width of the step-down portion 48a1. Further, a through-hole 50a3 is formed in the center of the central portion 50a1 of the hub 50a.

A pair of fitting portions 52 is projected from the flat portion 46a of the surrounding wall 46 of the case body 42. Those fitting portions 52 are so formed as to extend vertically at the same interval as that between the longer leg portions 36b of the paired terminal pins 36 of the speaker 20, and fit to the longer leg portions 36b when the longer leg portions 36b are pressed from the front side as described later.

Further, three unit attaching leg portions 54 protrude downward at intervals of 120° at the lower end portion of the surrounding wall 46 of the case body 42. A lower end portion of each of those unit attaching leg portions 54 is formed as a lance fitting portion 54a and inserted into a fitting hole for attachment (not shown) such as a base plate, to thereby lance-fit to its fitting hole.

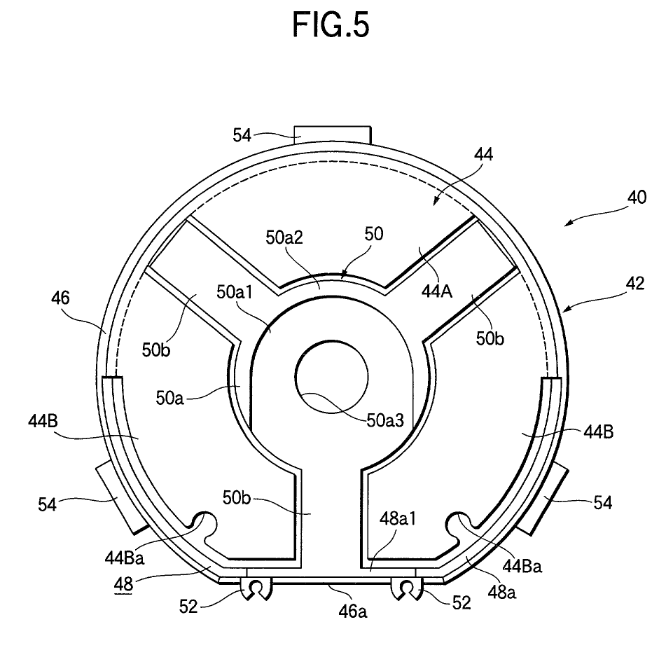

The protective cover 44 includes a press tab 44A located on the back side and a pair of right and left flexible levers 44B located on the front side. As shown in FIG. 5, the protective cover 44 is formed at the position where the cover 44 does not overlap with the beam 50 of the case body 42 when the case is seen from the upside.

Namely, the press tab 44A, viewed from the upper surface, is shaped in a fan at slight intervals between the hub 50a and the press tab 44A and between the two spokes 50b on the backside and the press tab 44A. Further, each of the flexible levers 44B is shaped substantially in a fan at slight intervals between the hub 50a and the flexible lever, between the spokes 50b on the front side and back side and the flexible lever, and between the lower end edge 48a of the opening portion 48 of the surrounding wall 46 and the flexible lever.

A base end portion of each of the flexible levers 44B is located on the backside of the opening portion 48 in the surrounding wall 46, and extends slightly inward toward the front side. This structure allows each flexible lever 44B to be elastically deformed in the right and left directions with its base end portion taken as the center. Further, an arcuate recess portion 44Ba that is substantially circular is formed in the vicinity of the leading end portion on an arcuate peripheral surface of each flexible lever 44B. Those recess portions 44Ba are formed at the same intervals as a pair of the right and left projections 34c formed on the upper end surface 34b of the ring 34. Further, each of those recess portions 44Ba is formed an inner diameter of which is slightly larger than the outer diameter of each projection 34c and an opening width of which is nearly the same as the outer diameter of each projection 34c.

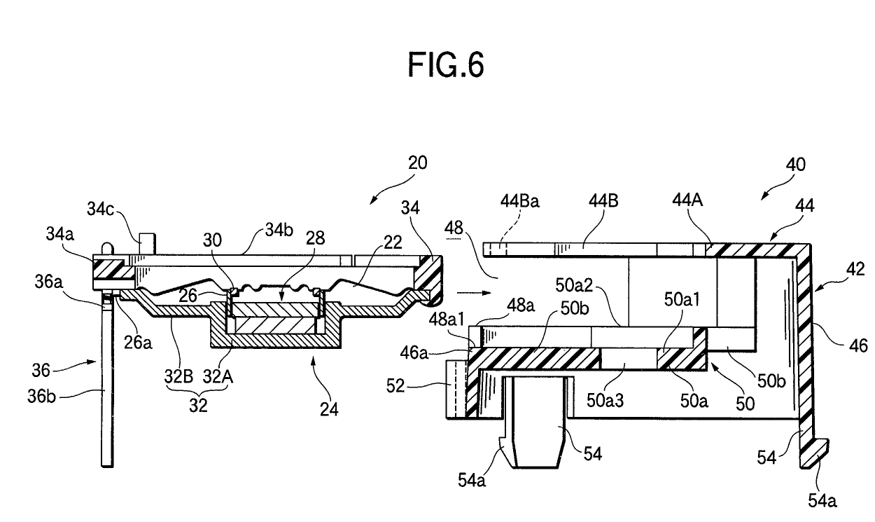

As shown in FIG. 6, the speaker 20 is inserted through the opening portion 48 into the case body 42 of the case 40 from the front side (the left side in FIG. 6), and held by the beam 50 and the protective cover 44 from its upside and downside in a state where the insertion of the speaker 20 has been completed.

Namely, the speaker 20 moves so that the lower end surface of the bottomed cylindrical portion 32A slides from the step-down portion 48a1 of the case body 42 to the central portion 50a1 of the hub 50a through the spoke 50b, and the outer peripheral surface of the bottomed cylindrical portion 32A comes into contact with the surrounding edge portion 50a2 of the hub 50a. Further, in insertion of the speaker 20, the upper end surface 34b of the ring 34 comes into sliding contact with the lower surface of the protective cover 44.

When the insertion is completed, a pair of projections 34c formed on the ring 34 of the speaker 20 fit to the recess portions 44Ba formed on a pair of the right and left flexible levers 44B of the protective cover 44.

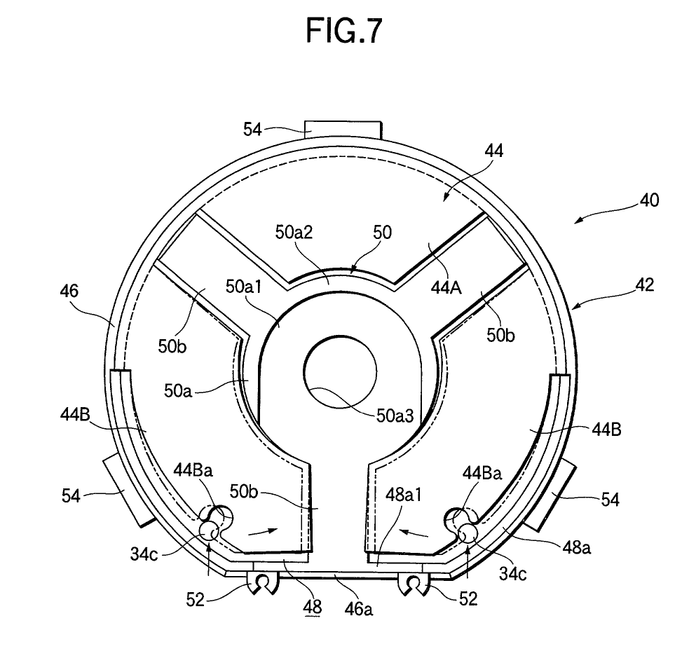

As shown in FIG. 7, the above fitting is performed in the following manner. When both the projections 34c come into contact with both the flexible levers 44B, the flexible levers 44B are elastically deformed so as to approach each other. Then, the projections 34c fit into the recess portions 44Ba of the flexible levers 44B to complete the insertion.

As shown in FIGS. 1 and 2, after completion of the insertion, each the projection 34c is caulked and fixed to each flexible lever 44B. The caulk fixing is performed by applying ultrasonic vibrations to each the projection 34c from the upside and subjecting the projection 34c to heat-deformation. By performing the caulk fixing, the speaker 20 is firmly fixed to the case 40.

Immediately before the completion of the insertion, the longer leg portion 36b of each the terminal pin 36 extending downward from the terminal attaching flange 34a of the ring 34 comes into contact with each the fitting portion 52 of the case body 42. At this time, by pressing each the longer leg portion 36b from the front side and fitting it into each the fitting portion 52, both the terminal pins 36 can be readily fixed to the case 40.

As described above, in the speaker unit 10 according to this invention, since the case 40 is formed of the synthetic resin member having the case body 42 and the protective cover 44 integrally molded, the number of parts to be used in the speaker unit is reduced by one, and no process of fixing the case body 42 and the protective cover to each other is required as compared with the conventional structure where the case body and the protective cover are formed of different members. Also, in the speaker unit 10 according to this embodiment, since the speaker 20 inserted into the case body 42 through the opening portion 48 formed in the surrounding wall 46 of the case body 42 is held by the beam 50 formed inside of the case body 42 and the protective cover 44, the case 40 having the integrally molded structure can be readily realized.

Therefore, according to this embodiment, the speaker unit having the speaker and the case for storing the speaker therein can be readily constituted as an integrally molded product, as a result of which the speaker unit can be manufactured at the low costs.

Further, in this embodiment, since the speaker 20 is held by the beam 50 and the protective cover 44 from its upside and downside in a state where it is inserted into the case body 42 through the opening portion 48, the speaker 20 can be readily inserted into the case 40.

Further, in this embodiment, since the beam 50 is formed at a position where the beam 50 does not overlap with the protective cover 44 when the case is seen from its upper surface, the case 40 can be molded without using a slide mold.

Further, in this embodiment, when the speaker 20 is inserted into the case body, the projections 34c formed on the frame 24 of the speaker 20 fit to the recess portions 44Ba formed on the protective cover 44. Therefore, the speaker 20 can be surely inserted into the case 40 with the simple constitution.

Further, in this embodiment, a part of the protective cover 44 is formed as a pair of the flexible levers 44B that extend opposite to the inserted direction of the speaker 20, and the recess portions 44Ba are formed respectively in the vicinity of the leading end portions of the flexible levers 44B. Therefore, the projections 34c can be fitted to the recess portions 44Ba due to elastic force of both the flexible levers 44B, so that fitting between the projection and the recess portion can be performed smoothly and firmly.

Further, since the projection 34c is caulked and fixed to the protective cover 44 in a state where the projection 34c fits to the recess portion 44Ba, the speaker 20 can be fixed to the case 40 more firmly. Therefore, also in the case that the speaker unit 10 according to this embodiment is used under the environments where large vibration and shock load act like a speaker unit mounted on an automobile, it can stand use sufficiently.

In this embodiment, the caulk fixing is performed by applying the ultrasonic vibration to the projections 34c and subjecting the projections 34c to the heat deformation. However, cold caulking can be adopted, needless to say.

Further, in this embodiment, the pair of terminal pins 36 extend downward from the peripheral edge portion of the frame 24 of the speaker 20, and fitting portions 52 that fit to the terminal pins 36 when the speaker is inserted are formed on the surrounding wall 46 of the case body 42. Therefore, each of the terminal pins 36 can be surely positioned at the predetermined position with respect to the case body 42. Accordingly, when the speaker unit 10 is attached to a base plate for attachment, attaching operation can be performed in a state where the positional relation between the unit attaching leg portion 54 of the case body 42 and each of the terminal pins 36 is kept accurate, whereby the attachment working capacity of the speaker unit 10 can be ensured.

Further, in the above embodiment, the beam 50 formed inside of the case body 42 is made up of the hub 50a and the three spokes 50b. However, other beam structures (for example, a beam structure in which cantilevers are protruded inward of the case body 42 from the portions on the right and left sides of the surrounding wall 46 of the case body 42) are also applicable.

Further, in the above embodiment, the example in which the speaker 20 is downsized is described. However, also in case that the size of the speaker is larger, by adopting the same constitution as that in the above embodiment, the same effects can be obtained as those in the above embodiment.

What is claimed is:

1. A speaker unit, comprising:
a speaker having a diaphragm; and
a case for storing said speaker therein, said case comprising a cylindrical case body and a protective cover for partially covering the diaphragm at the leading end of said case body;
wherein said cylindrical case body and said protective cover are integrally molded of synthetic resin;
wherein an opening portion is defined in a surrounding wall of said case body through which the speaker is inserted;
and
wherein a beam is formed inside of said case body, whereby said speaker is held by said beam and said protective cover in a state where said speaker is inserted into said case body.

2. The speaker unit according to claim 1, wherein said beam is formed at a position where said beam does not overlap with said protective cover when said case is seen from the leading end.

3. The speaker unit according to claim 1, wherein said speaker and said case include a fitting structure which fits to each other when said speaker is inserted into said case body.

4. The speaker unit according to claim 3, wherein said fitting structure comprises a projection formed on a frame of said speaker and a recess portion formed in said protective cover.

5. The speaker unit according to claim 4, wherein said projection is caulked and fixed to said protective cover in a state where said projection is fitted to said recess portion.

6. The speaker unit according to claim 4, wherein said protective cover includes a pair of flexible levers that extend opposite to the inserted direction of said speaker, and said recess portions are formed in the vicinity of the leading end portions of said flexible levers, respectively.

7. The speaker unit according to any one of claims 1 to 6, wherein said speaker has a pair of terminal pins that extend out of an peripheral edge portion of said speaker and said case body has fitting portions that fit to said terminal pins when said speaker is inserted into said case body on the surrounding wall of said case body.

8. The speaker unit according to claim 2, wherein said speaker and said case include a fitting structure which fits to each other when said speaker is inserted into said case body.

9. The speaker unit according to claim 5, wherein said protective cover includes a pair of flexible levers that extend opposite to the inserted direction of said speaker, and said recess portions are formed in the vicinity of the leading end portions of said flexible levers, respectively.
